(19) United States
(12) Patent Application Publication
(10) Pub. No.: US 2005/0088668 A1
(43) Pub. Date: Apr. 28, 2005

(54) System to communicate the present status of a job queue

(76) Inventors: Robert Sesek, Meridian, ID (US); Rhonda A. Grindstaff, Boise, ID (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/692,379

(22) Filed: Oct. 23, 2003

(51) Int. Cl. G06F 15/00; G03F 3/10

(52) U.S. Cl. 358/1.1; 358/527

(57) ABSTRACT

A method in a computer system for communicating the present status of a job queue that contains a plurality of jobs. The method may include controlling a display device to display a plurality of images. Each image may be a print preview image of a different one of the plurality of jobs in the job queue.

### BACKGROUND OF THE INVENTION

As used herein, the term “job” refers to a unit of work that is to be performed by a computing device. As used herein, the phrase “print job” describes any type of job that directs a printing device to print an image (e.g., document, digital photograph, etc).

Many printing devices can receive a print job electronically from, for example, a host computer. Some printing devices include a document scanner and allow a user to generate a print job by scanning a document. A print job that is generated in this manner may sometimes also be referred to as a “copy job”.

Jobs may sometimes be placed in a job queue prior to being processed by a device. For example, print jobs may be placed in a job queue prior to being processed by a printing device. Typically, the printing device will process each job in the order the jobs are lined up in the queue.

A user may wish to know the present status of a job queue. For example, a user may have interest in a particular job and wish to know where that job is positioned in the job queue with respect to other jobs. A user may also wish to manipulate the job queue in some manner. For example, a user may wish to change the way jobs are lined up in the job queue.

### BRIEF DESCRIPTION OF THE DRAWINGS

FIG. 1 is a block diagram of a printing system that is in accordance with an embodiment of the invention;

FIG. 2 is a block diagram of a printing device that is in accordance with an embodiment of the invention;

FIG. 3 is a flow diagram to illustrate an example of how the printing device may function to communicate the present status of a job queue;

FIG. 4A illustrates an example of how print preview images may be arranged on a display device according to an embodiment of the invention;

FIG. 4B illustrates an example of how print preview images may be arranged on a display device according to an embodiment of the invention;

FIG. 4C illustrates an example of how print preview images may be arranged on a display device according to an embodiment of the invention;

FIG. 5 is a flow diagram to illustrate an example of how a printing device may function to communicate the present status of a job queue according to an embodiment of the invention;

FIG. 6A illustrates an example of how images may be arranged on a display device according to an embodiment of the invention;

FIG. 6B illustrates an example of how images may be arranged on a display device according to an embodiment of the invention;

FIG. 6C illustrates an example of how images may be arranged on a display device according to an embodiment of the invention;

FIG. 7 is a flow diagram to illustrate a method that may be performed by a client and server to communicate the status of a job queue according to an embodiment of the invention;

FIG. 8 shows a WEB site that is in accordance with an embodiment of the invention;

FIG. 9 is a flow diagram to illustrate a method for communicating the present status of a job queue according to an embodiment of the invention;

FIG. 10 is a block diagram of a multifunction peripheral device that is in accordance with an embodiment of the invention; and

FIG. 11 is a flow diagram to illustrate an example of how the MFP of FIG. 10 may function.

### DETAILED DESCRIPTION OF THE INVENTION

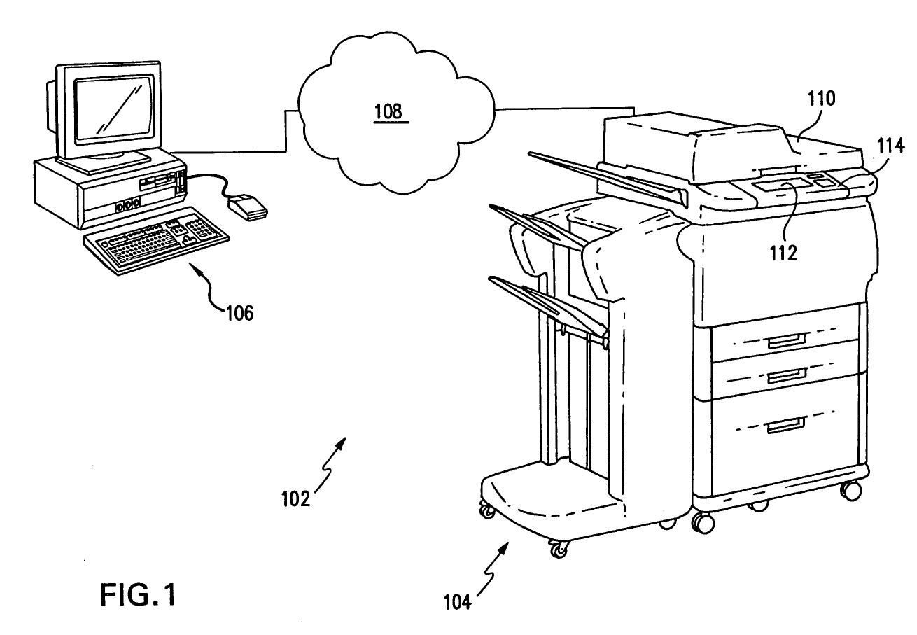

FIG. 1 shows an embodiment of the invention in the form of a printing system 102. The printing system 102 includes a printing device 104 coupled to a computer 106 via a communication link 108.

The communication link 108 may represent any type of communication path that allows data communication between two devices. For example, the communication link 108 may represent a serial cable, a parallel cable, a network system, a wireless link, the INTERNET, etc.

In this example, the printing device 104 is a multi-function device that includes both a document scan and a document print function. To enable the document scan function, the printing device 104 includes a document scanner 110.

A walk-up user to the printing device 104 may use the scanner 110 to perform a number of tasks. For example, a user may use the scanner 110 to convert a printed document into a copy job that is then printed by the printing device 104. As noted above a copy job is considered a type of print job for purposes of this document. A user may also use the scanner 110 to convert a printed document into an image file that is then transmitted to a remote destination.

A print job may also be electronically transmitted to the printing device 104 via the communication link 108. For example, the computer 106 (under the direction of a user) may generate and then transmit a print job to the printing device 104.

The printing device 104 further includes a local user interface 112 that enables the printing device 104 to both display information and receive input from a walk-up user. As shown, the user interface 112 includes a display device 114. The display device 114 may represent any suitable device capable of displaying the print preview images described below. In one implementation, for example, the display device 114 represents a touch screen.

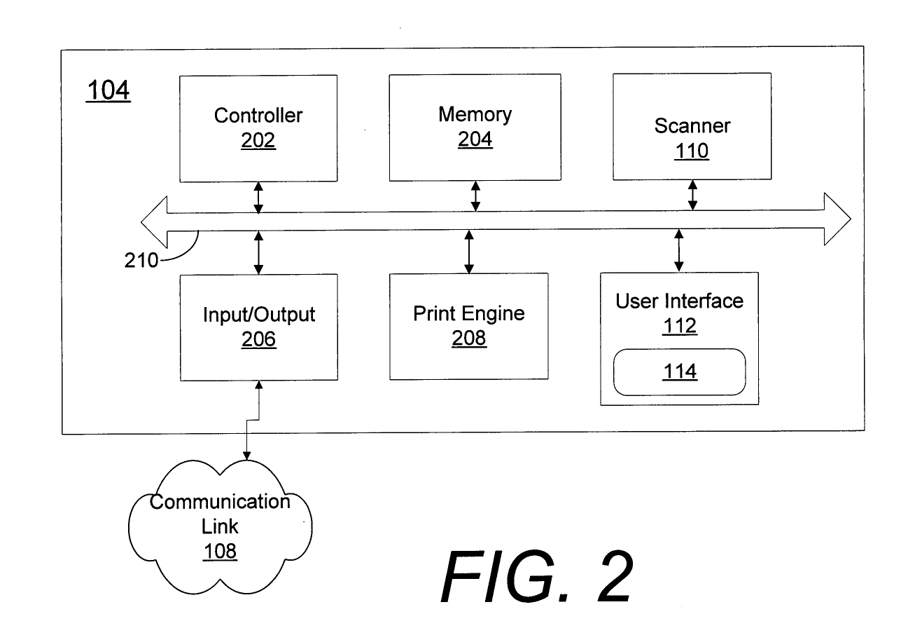

FIG. 2 is a high level block diagram of the printing device 104. As shown, the printing device 104 includes the following: a controller 202, a memory 204, an input/out port (I/O) 206 and a print engine 208. Also shown are the scanner 110 and the user interface 112. All these components may be coupled to a local bus system 210.

The (I/O) port 206 enables the printing device 104 to receive a transmission of a print job over the communication link 108. The print engine 208 includes the appropriate mechanisms to enable the printing device 104 to print on physical media. The print engine 208 may represent any type of print engine such as, for example, a laser print engine or an ink jet print engine.

The controller 202 controls the operation of the printing device 104, including the operation of the display device 114. It is noted that the controller 202 may include one or more hardware components and/or software components that enable the printing device 104 to perform the various functions described below. The software components may be stored in the memory 204.

Job Queue

It is noted for the later discussion that print jobs may be placed in a job queue prior to being processed by the printing device 104. In this embodiment, for example, the jobs that are presently in the job queue may be buffered in the memory 204. These jobs may have been generated locally by the use of the scanner 110 and/or electronically received over the communication link 108.

Communication of Job Queue Status

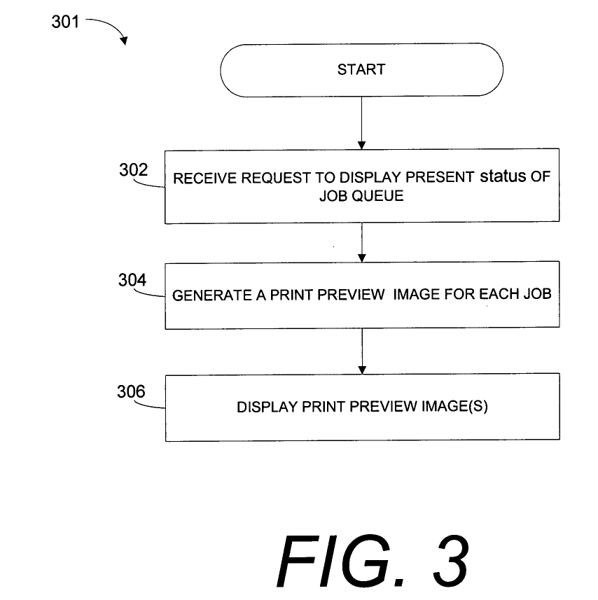

FIG. 3 shows a flow diagram 301 to illustrate an example of how the printing device 104 may function to graphically communicate the present status of the job queue.

At step 302, a request is received by the printing device 104 to communicate the present status of the job queue. This request may be received either remotely (e.g., over the communication link 108) or locally from a walk-up user. A walk-user may submit the request, for example, by using the user interface 112.

In response to receiving the request, the printing device 104 operates to generate a “print preview” image of each print job that is presently in the job queue (step 304). It is noted that in other embodiments the printing device may generate a print preview image of a subset of the jobs that are presently in the job queue.

As used herein, a “print preview” image of a print job refers to an image that shows how at least one page of a print job will look after printing. Thus, a print preview image of a multi-page job may be an image of the first page of the job or of multiple pages of the job. In this embodiment, the printing device 104 operates, at step 304, to generate a print preview image of the first page of each job that is presently In the job queue.

At step 306, the printing device 104 operates to communicate the present status of the job queue by displaying the print preview images on a display device. In this example, the images are arranged on the display device so as to indicate the way the jobs are presently lined up in the job queue.

It is noted that step 306 may be performed in any number of ways. In the present embodiment, the printing device 104 displays the images locally on the display device 114. In other embodiments, however, the printing device 104 may direct a remote device (e.g., the computer 106) to display the images.

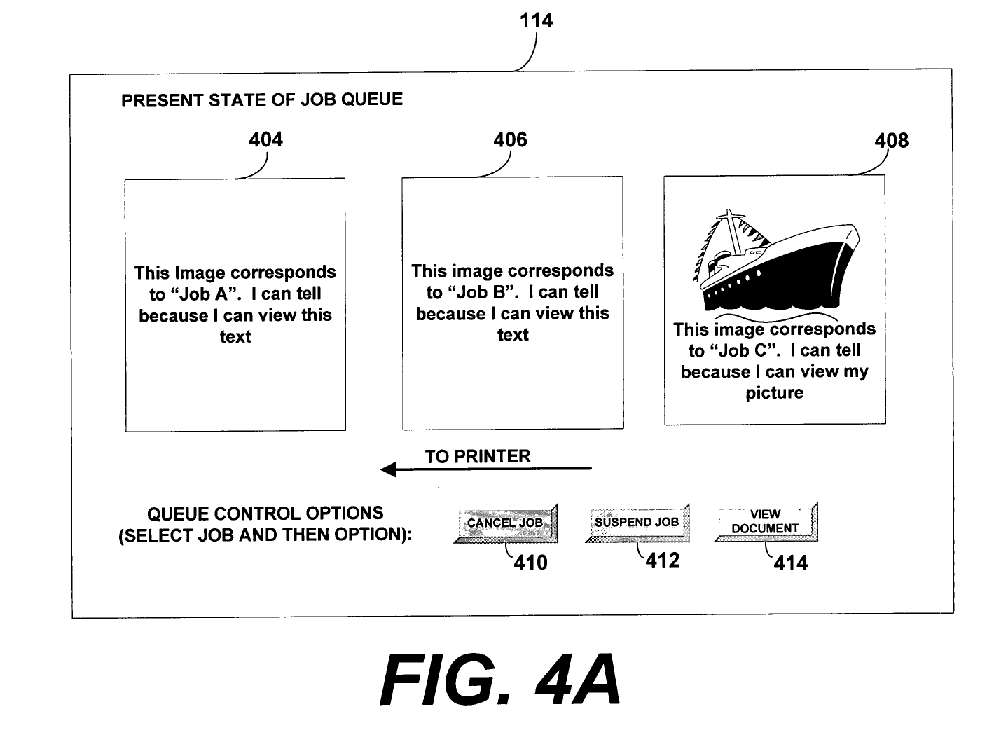

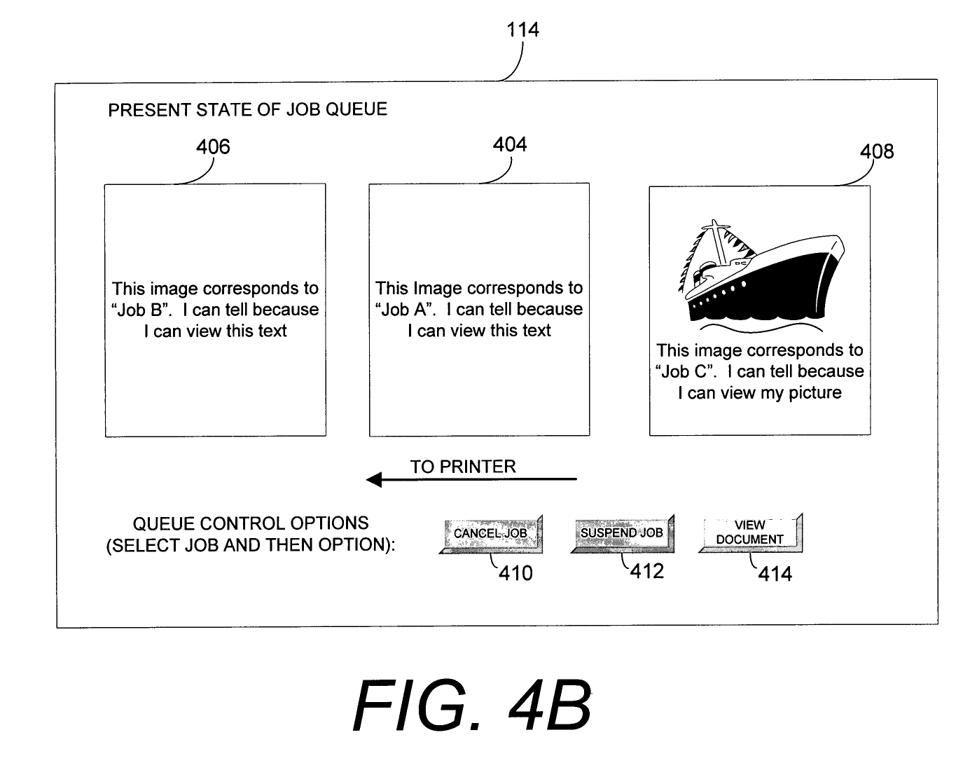

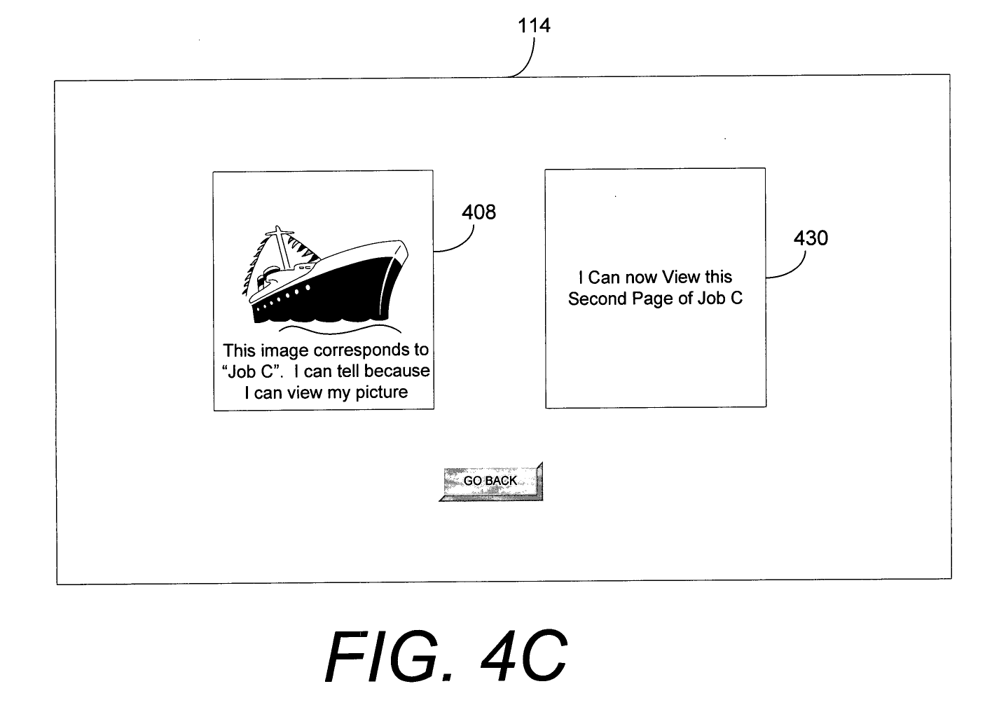

FIG. 4A illustrates an example of how the printing device 104 may arrange the print preview images on the display device 114. In this example, it is assumed there are three jobs presently in the job queue: Job A, Job B and Job C. It is noted that these jobs may have been originally created in any number of ways. For example, Job A may have been created by the computer 106 and electronically submitted to the printing device 104 via the communication link 108. Alternatively, Job A may have been generated locally by use of the scanner 110.

In this example, these three jobs are lined up in the job queue as follows: Job A is scheduled to be processed first, followed by Job B and then Job C.

As shown in FIG. 4A, the display device 114 displays a first image 404, a second image 406 and a third image 408. The first image 404 is a print preview image of the first page of Job A. The second image 406 is a print preview image of the first page of Job B. The third image 408 is a print preview image of the first page of Job C.

The three print preview images are arranged on the display device 114 according to a pre-determined convention so as to indicate the order the corresponding jobs are lined up in the queue. In this example, the images are arranged in a horizontal line from left to right. As shown in FIG. 4A, the first image 404 is displayed at the “head” of the line (which is furthest to the left in this example) followed by the second image 406 and then the third image 408. This arrangement is to convey to the viewer that Job A is first in line to be processed, followed by Job B and then Job C.

It is noted that in other embodiments different conventions can be used to arrange images on a display device to indicate the way the corresponding jobs are lined up in the job queue. For example, in some embodiments the images may be arranged on a display device from top to bottom. The image displayed at the very top, according to one convention, corresponds to the job in the job queue that is next in line to be processed.

Job Queue Manipulation

In this embodiment, the printing device 104 allows a user to manipulate jobs in the job queue by interacting, via the user interface 112, with the displayed print preview images.

A user, for example, may change the way jobs are lined up in the job queue by rearranging the displayed print preview images. Referring to FIG. 4A, in order to move Job B ahead of Job A in the job queue, the user may select the print preview image 406 and move this image (e.g., by dragging and dropping it) ahead of the print preview image 404. It is noted that a user may select an image in any number of ways. For example, if the display is a touch screen, the user may select an image by touching the displayed image.

In response to this user input, the printing device 104 may operate to:
(a) update the display device 114 as shown in FIG. 4B so that the second print preview image 406 is now displayed in front of the first print preview image 404; and
(b) move Job B ahead of Job A in the job queue.

The printing device 104 may also allow a user to cancel a job in the job queue by interacting with the displayed print preview images. For example, the printing device 104 may provide a cancel option 410 as shown in FIG. 4A. In order to cancel a job, a user may select a print preview image and then select the “cancel job” option 410. In response to this input, the printing device 104 may operate to cancel the corresponding job in the job queue.

The printing device 104 may also allow a user to suspend a job in the job queue by interacting with the displayed print preview images. For example, the printing device 104 may provide a “suspend job” option 412 as shown in FIG. 4A. In order to suspend a job, a user may select the print preview image that corresponds to the job and then select the suspend job option 412. In response to this input, the printing device 104 may operate to suspend the corresponding job. A suspended job may be held by the printing device 104 and not printed until released by a user.

The printing device 104 may also allow a user to view the image described by a particular job in more detail. For example, the printing device may provide a “view document” option 414 as shown in FIG. 4A. A user may select a print preview image and then select this option. In response to this input, the printing device 104 may operate to generate a new print preview image that is at a higher resolution and/or shows additional pages of a job. The printing device 104 then displays the new print preview image.

Thus, for example, if the user selects the print preview image 408 and then selects the view document option 414, the printing device 104 may generate a new print preview image of multiple pages of Job C. FIG. 4C illustrates an example of how the printing device 104 may display the new print preview image on the display device 114 according to one specific implementation. As shown, a print preview image of two pages is displayed. The first image 408 is a view of the first page of job C. The second image 430 is a view of the second page of Job C.

Additional Options

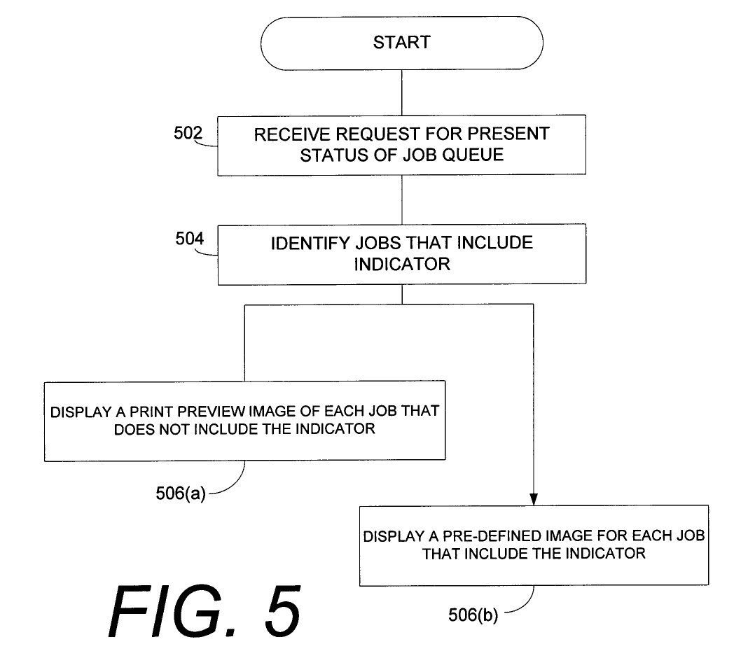

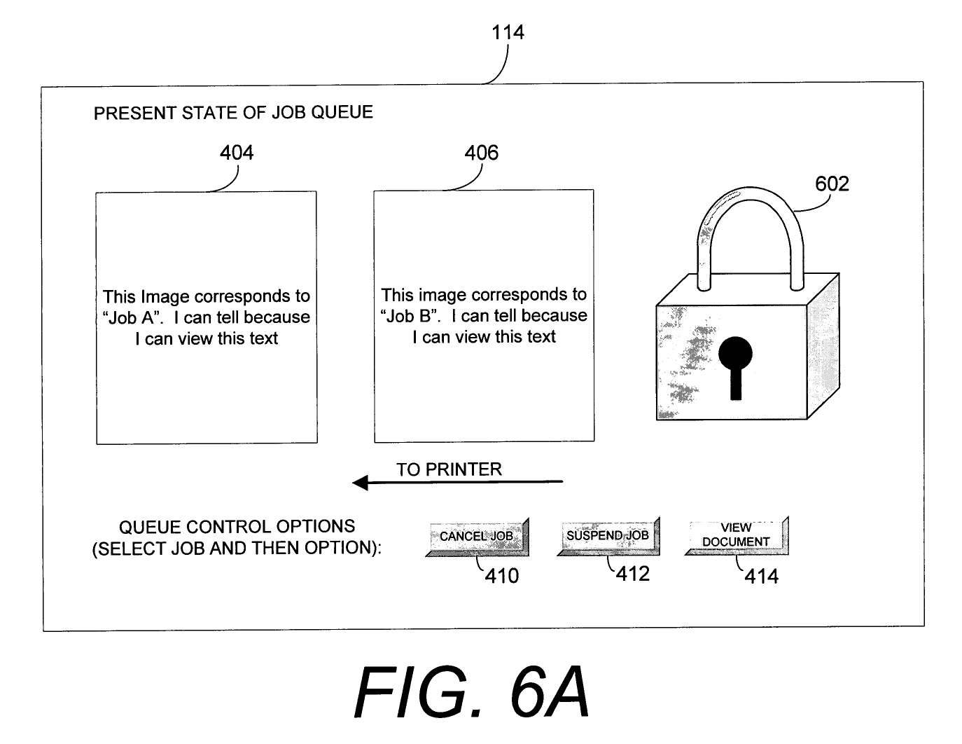

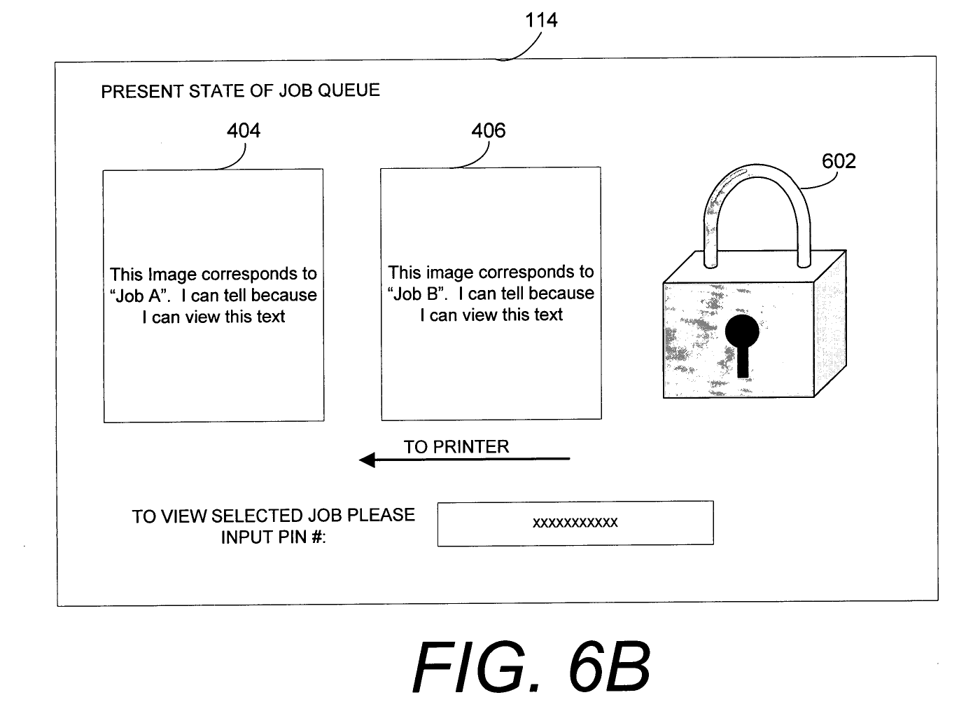

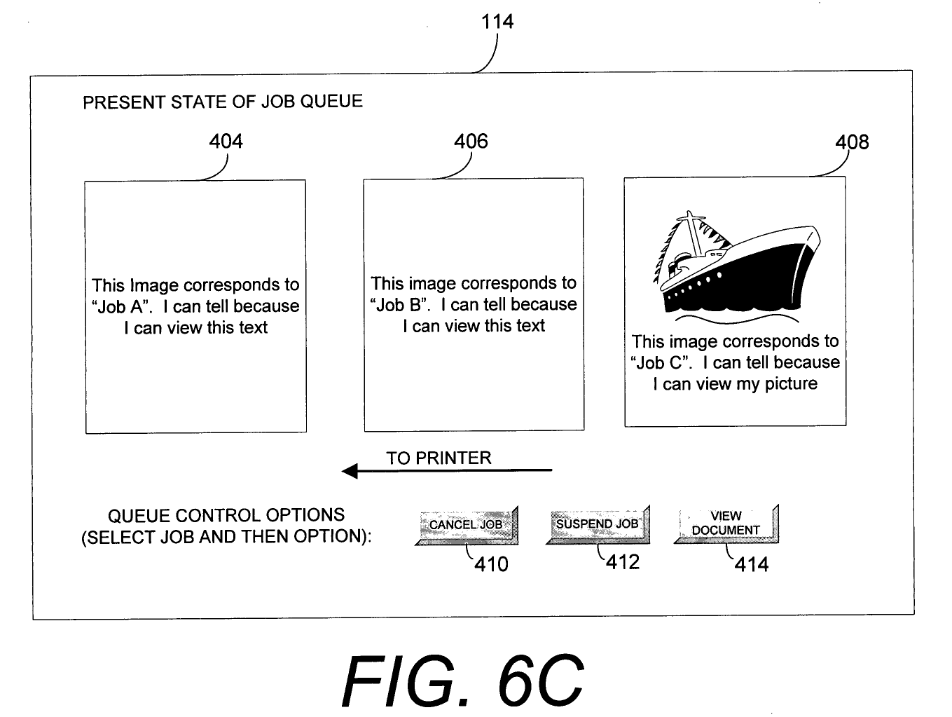

It is noted that in some embodiments a printing device may be configured to display a print preview image of some jobs and not others. To illustrate an example of one such an embodiment, attention is directed to FIG. 5 and FIGS. 6A-C.

FIG. 5 is a flow diagram to illustrate another example of how a printing device may function to communicate the present status of a job queue that contains a set of print jobs. At step 502, a request is received to communicate the present status of the job queue. In response to this request, the jobs that include a pre-defined indicator are identified (step 504). The indicator may indicate, for example, that a print preview image is to be displayed only after a certain PIN number is entered.

The printing device then proceeds to display a print preview image of each job that does not include the indicator (step 506(a)). Additionally, the printing device operates to display a pre-defined image for each job that includes the indicator (step 506(b)). The pre-defined image, in this embodiment, is not a print preview image and does not provide a view of the printable information in the corresponding job.

FIG. 6A illustrates an example of how step 506(a) and step 506(b) may be performed assuming the same job queue conditions exist as described with reference to FIG. 4A. In this example, however, Job C includes an indicator that indicates a print preview image is not to be displayed until a particular PIN number is entered.

As indicated in FIG. 6A, the display device 114 displays a print preview image of Job A and Job B. A pre-defined image 602 is, however, displayed in place of a print preview image of Job C. In this example, the pre-defined image 602 is an image of a lock so as to convey to the user that the corresponding job is considered a private job. It is noted that the pre-defined image 602 does not show any of the printable information contained in Job C. The image 602 does, however, convey the position of Job C in the job queue by virtue of its placement with respect to the other two images.

When the image 602 is selected, the printing device 104 may update the display device 114 so as to prompt a user to enter a PIN number (see FIG. 6B). Upon the PIN number being entered, the printing device 104 updates the display device 114 so that the print preview image 408 is now displayed as shown in FIG. 6C.

Client/Server Systems

It is noted that the invention may be embodied in a client/server system. The following discussion illustrates an example of one such embodiment.

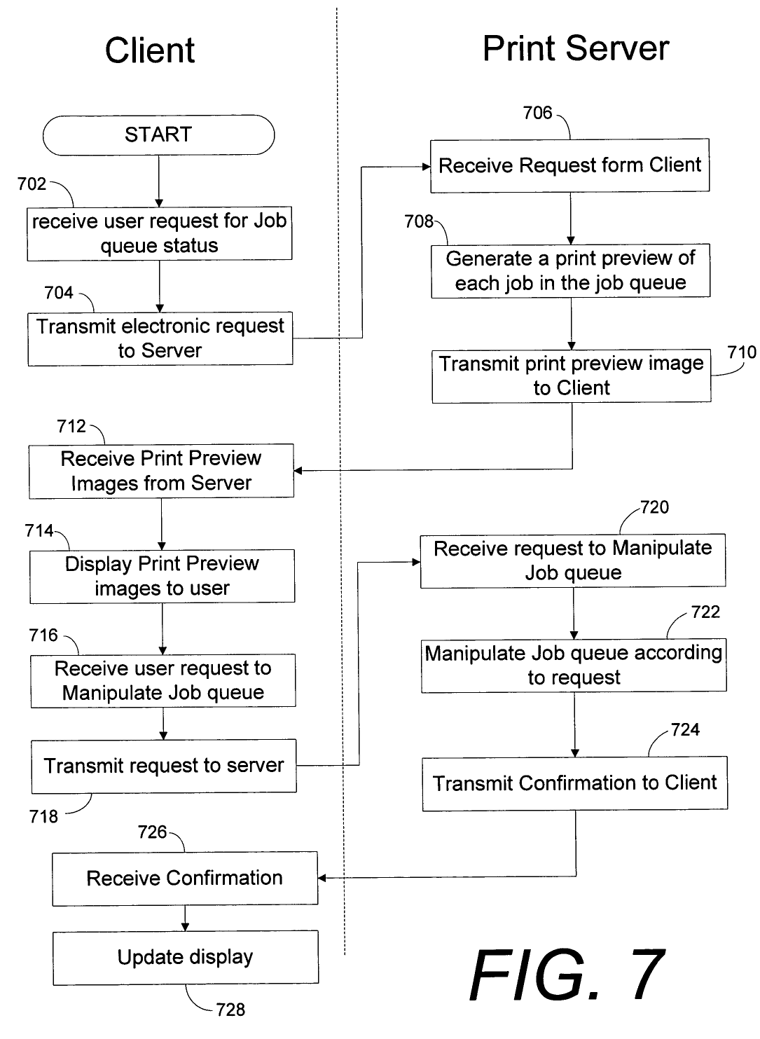

FIG. 7 is a flow diagram to illustrate a method that may be performed by a client (e.g., the computer 106) and a print server to communicate the status of a job queue. It is assumed that the client includes a local display device and a user input device (e.g., a keyboard and/or a pointer device). The job queue may be located on the print server and may service a particular printing device that is remote from both the client and the print server. In other embodiments, the print server may reside on the printing device itself.

Referring now to FIG. 7, the client receives a request from a user for the present status of the job queue (step 702). The request may include some sort of user authentication, such as a PIN number. In response to the user request, the client transmits a request electronically to the print server for the present status of the job queue (step 704).

The print server receives the request at step 706. In response to the request, the print server generates a print preview image of each print job in the job queue (step 708). At step 710, the print server transmits the print preview images back to the client. The print server may also communicate the order the jobs are lined up in the queue at this step. This may be accomplished, for example, by transmitting the images back to the client in the same order the corresponding jobs are lined up in the job queue.

The client receives the print preview images from the server at step 712. At step 714, the client displays the print preview images. The displayed images may be arranged so as to indicate the order the corresponding jobs are lined up in the job queue.

At step 716, the client receives a user request to manipulate the job queue. For example, the user request may be a request to rearrange the jobs in the job queue. At step 718, the client transmits a request to the server to manipulate the job queue as per the user's request.

At step 720, the server receives the request. At step 722, the server operates to manipulate the Job queue in accordance with the request received at step 720. At step 724, the print server sends a confirmation back to the client that the job queue was manipulated as per the user request.

At step 726, the client receives the confirmation. At step 728, the client may update the display to convey to the viewer that his/her request to manipulate the job queue was successful.

Other Embodiments

It is also noted that the present invention may be embodied in the form of a “computer-readable medium”. As used herein, the phrase “computer-readable medium” can refer to any medium that can contain, store or propagate computer executable instructions. Thus, in this document, the phrase “computer-readable medium” may refer to a medium such as an optical storage device (e.g., a Compact Disc), a magnetic storage device (e.g., a magnetic tape), a semi-conductor storage device, etc. The phrase “computer-readable medium” may also refer to signals that are used to propagate the computer executable instructions over a network or a network system, such as the Public Internet.

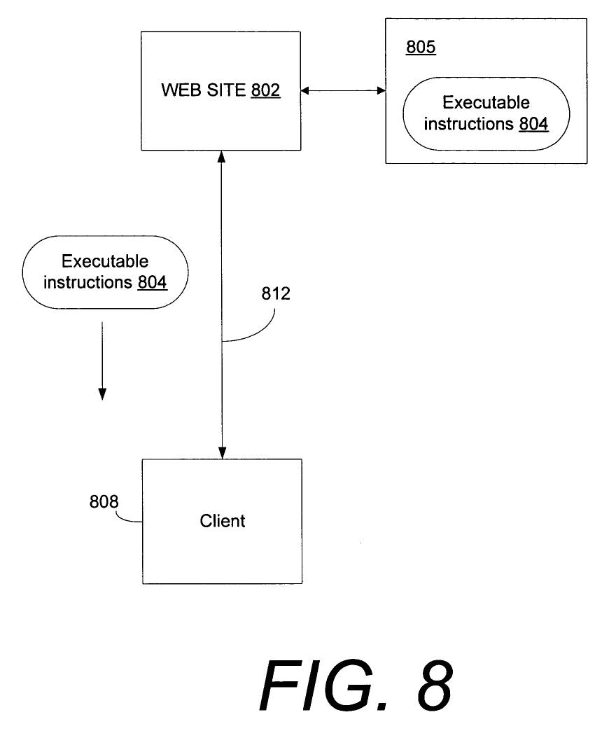

FIG. 8 illustrates yet another embodiment of the invention. FIG. 8 shows a WEB site 802 that includes a memory 805. The memory 805 stores a set of computer executable instructions 804. The instructions 804 may represent instructions that are executable by a processor to perform any of the steps depicted in the flow diagrams described above.

For example, according to one implementation the instructions 804 are executable by a processor to perform the steps depicted in FIG. 3. In other implementations, for example, the instructions 804 are executable by a processor to perform one or more of the steps performed by the client of FIG. 7. In other implementations, the instructions 804 are executable by a processor to perform one or more of the steps depicted by the server of FIG. 7.

A Web Client 808 can download the instructions 804 over a network 812. The network 812 may represent, for example, the Public Internet.

The memory 805 is a type of computer-readable medium and represents an embodiment of the Invention. Additionally, the signals used to propagate the instructions over the network 812 are also considered a type of computer-readable medium. These signals represent yet another embodiment of the invention.

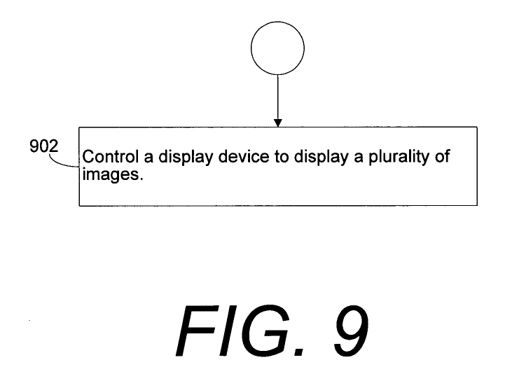

FIG. 9 illustrates another embodiment in the form of a method in a computer system for communicating the present status of a job queue. The job queue may contain a plurality of print jobs. As shown in FIG. 9, the method includes a single step: controlling a display device to display a plurality of images (step 902). Each image may be a print preview image of a different one of the plurality of print jobs in the job queue. It is noted that the job queue may service a particular device (e.g., a printing device). In some implementations, the display device may be local display device for the printing device. In other implementations, the display device may be located remotely to the printing device.

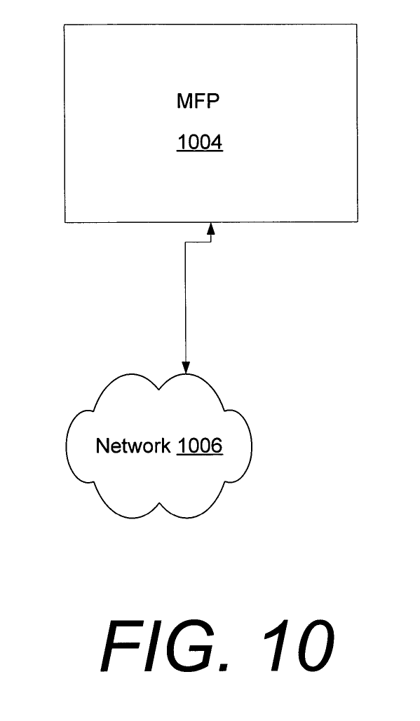

FIG. 10 is a block diagram of a multifunction peripheral device (MFP) 1004 connected to a network 1006. The MFP 1004 incorporates an embodiment of the invention. A user can use the MFP 1004 to scan documents and then digitally transmit the scanned documents to another device (not shown) connected to the network 1006.

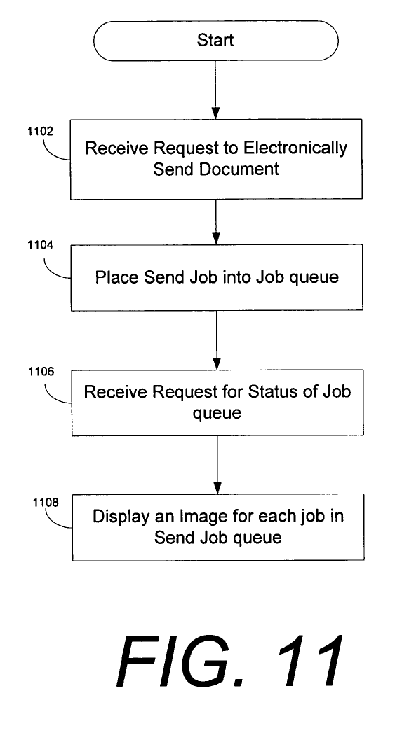

FIG. 11 is a flow diagram to illustrate an example of how the MFP 1004 may function when certain conditions exist. Referring to FIG. 11, at step 1102 the MFP 1004 receives a request to digitally send a document (document “A”) to a first destination (destination “A”).

In response to the request, the MFP 1004 may place a job to fulfill the request in a job queue (step 1104). The MFP 1004 may take this action, for example, because the MFP 1004 is presently busy performing some other task. For ease of discussion, this type job may alternatively be referred to herein as a “send job”.

At step 1106 the MFP 1004 receives a request to display the present status of the job queue. In response to the request, the MFP 1004 operates to display a set of images (step 1108). Each image corresponds to a different “send job” in the job queue. One of the images displayed is an image of document “A”. This image corresponds to the send job placed in the job queue at step 1104. The set of images may be arranged so as to convey the order the jobs are presently lined up in the queue.

Although several specific embodiments of the invention have been described and illustrated, the invention is not to be limited to specific forms or arrangements of parts so described and illustrated. The invention is limited only by the claims and the equivalents thereof.

1. A method in a computer system for communicating the present status of a job queue that contains a plurality of print jobs, comprising:
controlling a display device to display a plurality of images; and
wherein each image is a print preview image of a different one of the plurality of print jobs in the job queue.

2. The method of claim 1, wherein the plurality of images are displayed simultaneously.

3. The method of claim 1, wherein the plurality of images are displayed simultaneously and the images are displayed in an arrangement indicative of an order the plurality of jobs are presently lined up in the queue.

4. The method of claim 3, further comprising:
receiving a request to line up the jobs in the job queue in a different order;
in response to the request, rearranging the jobs in the job queue so that the jobs are lined up in the different order; and
in response to the request, controlling the display device to display the images in a modified arrangement, wherein the modified arrangement indicates the jobs are lined up in the different order.

5. The method of claim 3, further comprising:
receiving a request to view multiple pages of a selected one of the images, wherein the selected image is a print preview image of a single page of a first job from the plurality of jobs; and
in response to the request, controlling the display device to display a print preview image of multiple pages of the first job.

6. The method of claim 1, wherein the method is performed by a computer device coupled to a printing device over a communication link; and
wherein the job queue services the printing device.

7. The method of claim 1, wherein the method is performed by a printing device and the display device is local to the printing device.

8. The method of claim 1, wherein the controlling step is not performed until at least one personal identification number (PIN) is received.

9. The method of claim 4, wherein the request is received by a user dragging and dropping at least one of the displayed images.

10. A printing device serviced by a job queue, comprising:
means for receiving a request for the present status of the job queue; and
means for responding to the request by:
(i) generating a print preview image of at least some of the jobs in the job queue when the job queue includes a plurality of jobs; and
(ii) displaying the print preview images.

11. The printing device of claim 10, wherein the responding means displays the print preview images in an arrangement that is indicative of the way the corresponding jobs are lined up in the job queue.

12. The printing device of claim 10, wherein the responding means displays the print preview images in an order based upon an order the corresponding jobs are lined up in the job queue.

13. The printing device of claim 10, further comprising:
means for receiving a selection of one of the displayed images, wherein the selected image is a print preview image of a first job in the job queue;
means for receiving a request to cancel a job the selected print preview image represents; and
means for responding to the request by canceling the first job.

14. The printing device of claim 10, further comprising:
means for receiving a user selection of one of the displayed images, wherein the selected image is a print preview image of a first job in the job queue;
means for receiving a request to suspend a job the selected print preview image represents;
means for responding to the request by suspending the first job.

15. The printing device of claim 10, wherein the responding means simultaneously displays the print preview images on a display device in an arrangement that is indicative of the way the corresponding jobs are lined up in the job queue and the printing device further comprising:
means for allowing a user to change the way the jobs are lined up in the job queue by rearranging the print preview images.

16. A printing device, comprising:
a display device;
a controller; and
wherein the controller includes the capability to:
(a) generate a print preview image of a job in a job queue; and
(b) control the display device to display the print preview image.

17. The printing device of claim 16, wherein the controller includes the capability to:
(c) generate a print preview image of multiple jobs in the job queue when the job queue contains a plurality of jobs;
(d) control the display device to simultaneously display at least some of the print preview images of the multiple jobs.

18. The printing device of claim 16, wherein the controller includes the capability to:
(c) generate a print preview image of a set of jobs in the job queue when the job queue contains a plurality of jobs;
(d) control the display device to simultaneously display the print preview images in an arrangement that indicates the way the set of jobs are lined up in the job queue.

19. A method in a computer system for communicating the present status of a job queue that contains a plurality of jobs, comprising:
(a) identifying those jobs in the queue that include an indicator that indicates a print preview image of the job should not be displayed;
(b) displaying a print preview image of each job in the job queue not identified at step (a);
(c) displaying a pre-defined image for each job in the job queue identified at step (a); and
wherein the pre-defined image does not reveal any of the printable information described by the corresponding job.

20. The method of claim 19, wherein step (b) and step (c) are performed substantially simultaneously.

21. The method of claim 19, wherein the displayed images are arranged so as to indicate the order the plurality of jobs are lined up in the job queue.

22. The method of claim 19, wherein the pre-defined image is an image of a lock.

23. A method in a computer system for communicating the present status of a job queue that contains a plurality of print jobs, comprising:
transmitting a request to a print server, where the print server is responsive to the request by returning a plurality of images each image being a print preview image of a different job in the job queue;
receiving the plurality of print preview images; and
displaying at least some of the print preview images.

24. The method of claim 24, wherein the print preview images are displayed in an arrangement that is indicative of the way the corresponding jobs are lined up in the job queue.

25. A method in a computer system for communicating the present status of a job queue that contains a plurality of print jobs, comprising:
receiving a request from a client,
responding to the request by transmitting at least one image to the client;
wherein the image is a print preview image of one of the plurality of jobs.

26. One or more computer-readable that includes computer executable instruction for graphically communicating a present status of a job queue, the instructions including:
first instructions for responding to a request for a present status of a job queue by displaying a print preview image of at least some of the jobs in the job queue.

27. The computer readable medium of claim 27, wherein the print preview images are displayed in arrangement that indicates an order the print jobs are lined up in the job queue.

28. A method in a computer system, comprising:
receiving a first request to transmit an electronic document to a remote destination,
in response to the first request, placing a send job in a queue;
receiving a second request for the present status of the queue;
responding to the request, at least in part, by displaying an image of at least a portion of the document.
